(19) United States
(12) Patent Application Publication
(10) Pub. No.: US 2012/0280710 A1
(43) Pub. Date: Nov. 8, 2012

(54) REUSE OF CONSTANTS BETWEEN ARITHMETIC LOGIC UNITS AND LOOK-UP-TABLES

(75) Inventors: ANTHONY STANSFIELD, Bristol (GB); SIMON DEELEY, Bristol (GB)

(73) Assignee: PANASONIC CORPORATION, Osaka (JP)

(21) Appl. No.: 13/552,915

(22) Filed: Jul. 19, 2012

Related U.S. Application Data
(63) Continuation of application No. PCT/EP2010/055485, filed on Apr. 23, 2010.

(51) Int. Cl. H03K 19/173

(52) U.S. Cl. 326/38

(57) ABSTRACT

A combinatorial processing element used in a reconfigurable logic device having a plurality of processing elements interconnected by way of a routing network. The combinatorial processing element includes an arithmetic logic unit, having at least one input, a multiplexer tree, having a data input and a memory device. The processing element is arranged such that the memory can be connected to the data input of the multiplexer tree and/or the at least one input of the arithmetic logic unit.

The present invention relates to the field of reconfigurable logic devices. More specifically, the present invention relates to the use of Arithmetic Logic Units (ALUs) and Look-up-Tables (LUTs) in reconfigurable logic devices.

A reconfigurable logic device typically comprises an array consisting of multiple instances of a basic processing element (often referred to as a “CLB” (for Configurable Logic Block), or a “tile”), together with a routing network connecting the tiles together (disclosed in, for example, U.S. Pat. No. 6,353,841 and US2002/0157066). Other functional blocks may also be included in the device, which functional blocks may be used to perform dedicated functions.

Two classes of reconfigurable logic devices are LUT-based Field Programmable Gate Arrays (FPGAs) and ALU arrays.

LUT-based FPGAs use Look-up-Tables (LUTs), a small memory that is used to store the truth table of a Boolean function. LUTs typically have a small number of single-bit inputs (usually between 3 and 6), and produce a single-bit output.

In ALU arrays, the basic processing element is a circuit (ALU) capable of implementing arithmetic functions (normally Add and Subtract, as well as occasionally Multiplication), comparison functions (Equals, NotEquals) and logic functions (such as bitwise AND, OR, XOR and NOT). ALUs typically have have 2 word-wide inputs, and a single-bit carry output. Word lengths vary, with the smallest common value being 4 bits. Other common values are 8, or 32 bits.

Each of the above reconfigurable processing devices has its own advantages. For example, LUT-based devices tend to be more flexible, as they can implement any Boolean function of their input, whilst ALU-based devices are generally faster when implementing typical operations of word-wide data.

Thus, it would be advantageous to have a system which provides both ALU and LUT functionality. The disadvantage of such a system however is that it requires a large amount of routing resources in order to have the LUTs and ALUs work together. Moreover, adding these independent ALUs and LUTs results in an array which has an area that comprises the sum of the areas of these separate components.

Accordingly, an object of the present invention is to combine ALU and LUT functionality in a reconfigurable logic device such that the resulting circuit does not unduly burden the logic device's routing network. Another object of the present invention if to share components between ALUs and LUTs in order to reduce total area.

In order to solve the problems associated with the prior art, the present invention provides a combinatorial processing element used in a reconfigurable logic device having a plurality of processing elements interconnected by way of a routing network, the combinatorial processing element includes:

an arithmetic logic unit, having at least one input;

a multiplexer tree, having a data input; and

a memory device,

wherein the processing element is arranged such that the memory can be connected to the data input of the multiplexer tree and/or the at least one input of the arithmetic logic unit.

Preferably, the combinatorial processing element further comprises:

an input arranged to be connected to the routing network of the reconfigurable device.

Preferably, the at least one input of the arithmetic logic unit is an N-bit input;

the multiplexer tree further comprises M select inputs and 2^{M} data inputs, the multiplexer tree being arranged to select any of the 2^{M} data inputs; and

the memory device is an N-bit memory device arranged to be connected to the N-bit input of the ALU and/or to N of the 2^{M} data inputs of the multiplexer tree.

Preferably, N is smaller or equal to one half of 2^{M} and the combinatorial processing element further comprises:

a plurality of memory devices, wherein each of the plurality of memory devices is arranged to be connected to a separate input of the arithmetic logic unit and/or separate data inputs of the multiplexer tree.

Preferably, the at least one input of the arithmetic logic unit is an N-bit input;

the multiplexer tree comprises M select inputs and an N-bit data input, the multiplexer tree being arranged to select one bit of the N-bit data input; and

the memory device is an N-bit memory device arranged to be connected to the N-bit input of the ALU and/or to N of the 2^{M} data inputs of the multiplexer tree.

Preferably, the combinatorial processing element further comprises:

at least one N-bit input connected to the routing network of the reconfigurable logic device.

Preferably, the sum of N-bit inputs of the ALU and N-bit inputs of the multiplexer tree is more than the number of N-bit inputs connected to the routing network of the reconfigurable logic device.

Preferably, the memory devices are registers which are connected to the routing network of the reconfigurable logic device.

The present invention further provides a reconfigurable logic device which comprises:

a combinatorial processing element in accordance with any one of the preceding claims.

Preferably, at least one combinatorial processing element is arranged to provide a gateway between a single-bit routing network and a multi-bit routing network in the reconfigurable logic device.

As will be appreciated, the present invention provides several advantages over the prior art. For example, because a single local memory is used for both the LUT and the ALU, it is possible to combine the functionality of these devices without using up valuable routing resources. Moreover, and as a consequence of having the LUT and ALU use the same local memory resource, the combined operation of the LUT and ALU can be executed at much higher speeds than those exhibited by a circuit configured to combine a LUT and an ALU across the routing network of a reconfigurable logic device. Also, the sharing of constants between LUTs and ALUs avoids the need for separate storage for LUT constants and ALU input constants, or for extra registers elsewhere in the array to optionally store constants. Furthermore, the ability to use the multiplexer tree as either LUT or bit extraction circuit reduces the number of dedicated bit extraction circuits needed.

Specific embodiments of the present invention will now be described with reference to the accompanying drawings, in which:

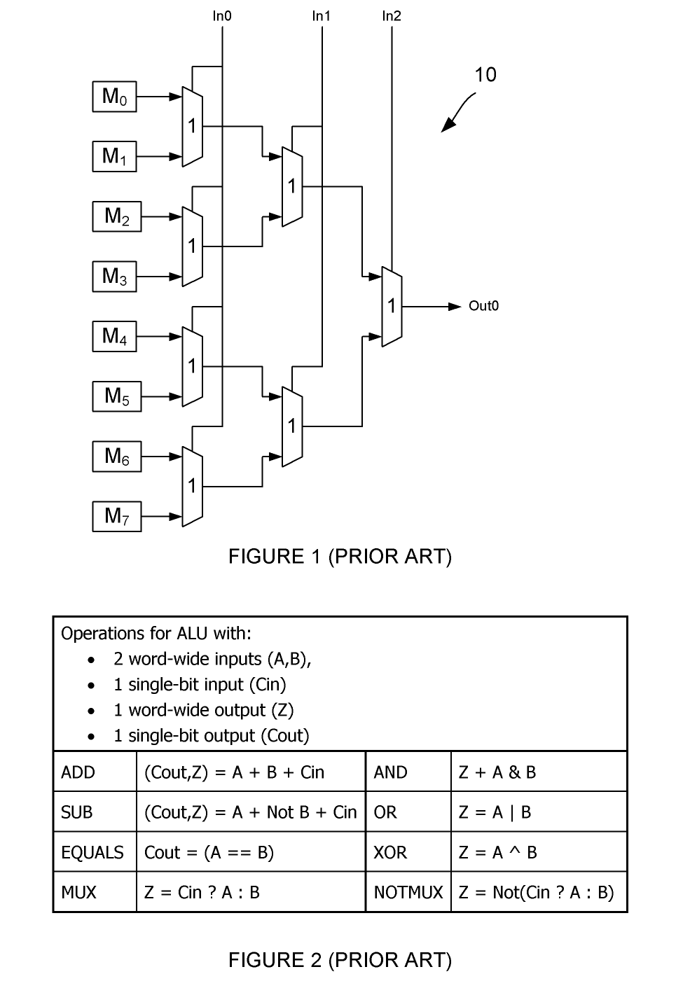

FIG. 1 is a functional diagram of a Look-up-Table (LUT) in accordance with one example from the prior art;

FIG. 2 is a table showing the functionality of an Arithmetic Logic Unit in accordance with one example from the prior art;

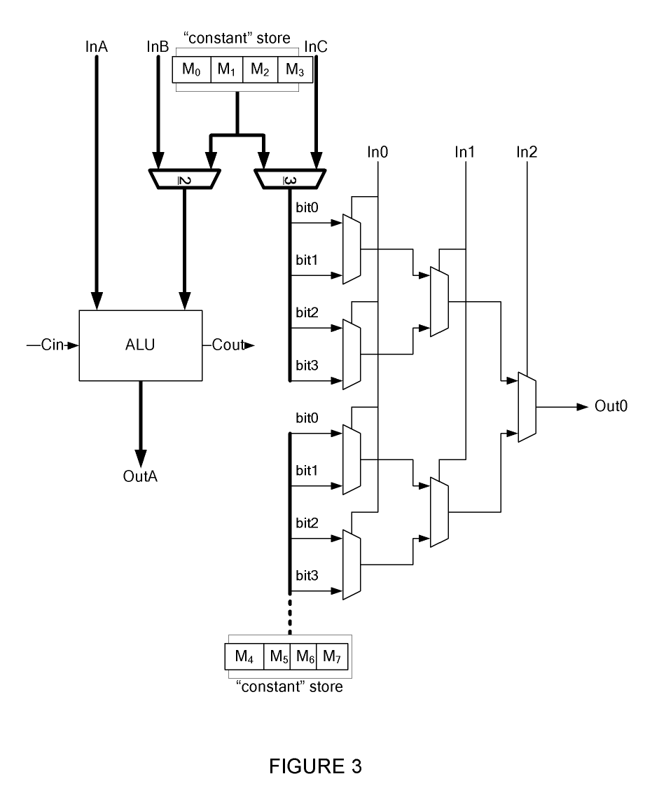

FIG. 3 is a functional diagram of a circuit in accordance with one embodiment of the present invention;

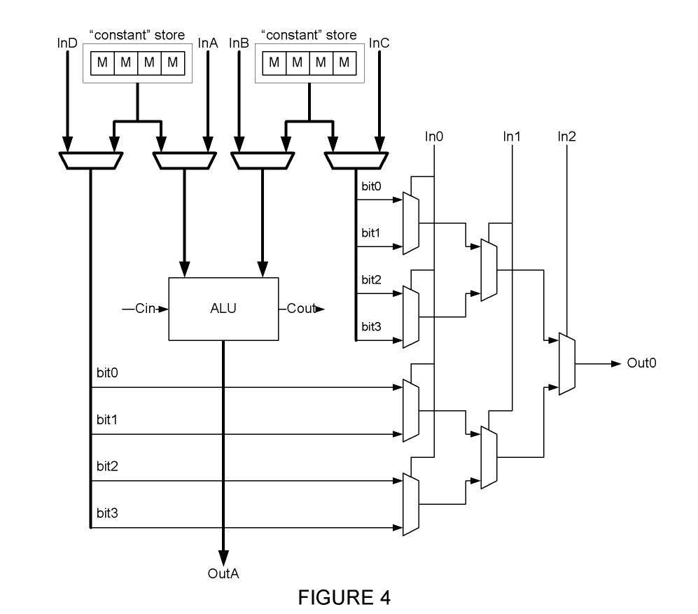

FIG. 4 is a functional diagram of a circuit in accordance with another embodiment of the present invention;

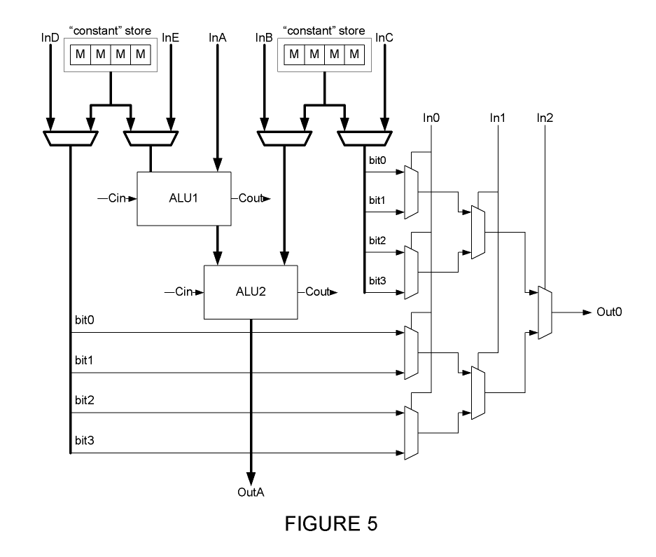

FIG. 5 is a functional diagram of a circuit in accordance with yet another embodiment of the present invention;

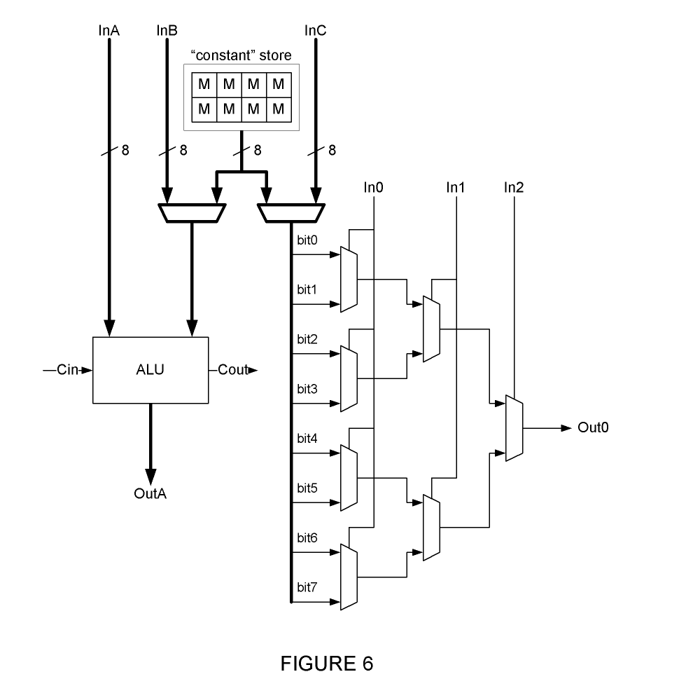

FIG. 6 is a functional diagram of a circuit in accordance with a further embodiment of the present invention;

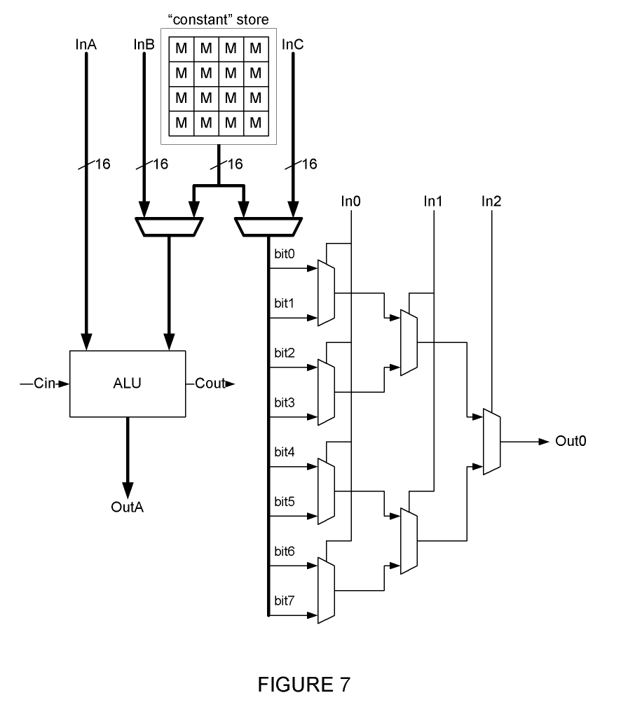

FIG. 7 is a functional diagram of a circuit in accordance with a further embodiment of the present invention;

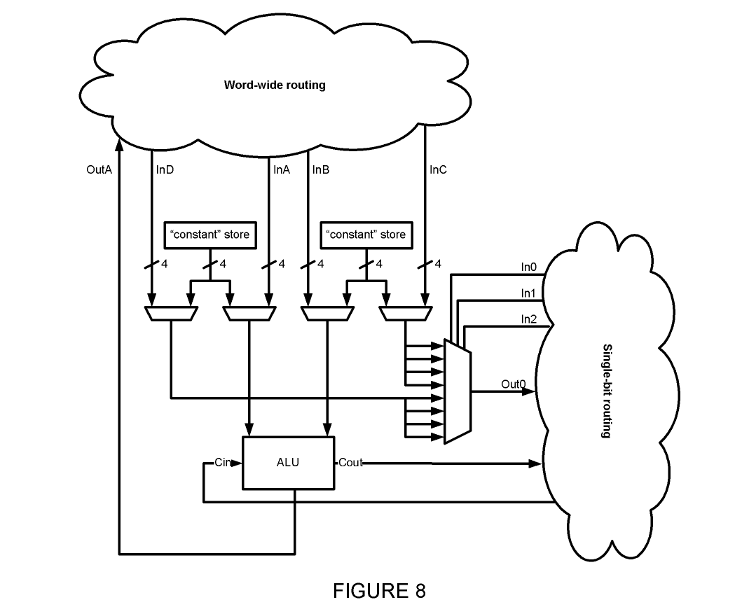

FIG. 8 is a functional diagram of a how the present invention can be connected to a routing network of a reconfigurable logic device;

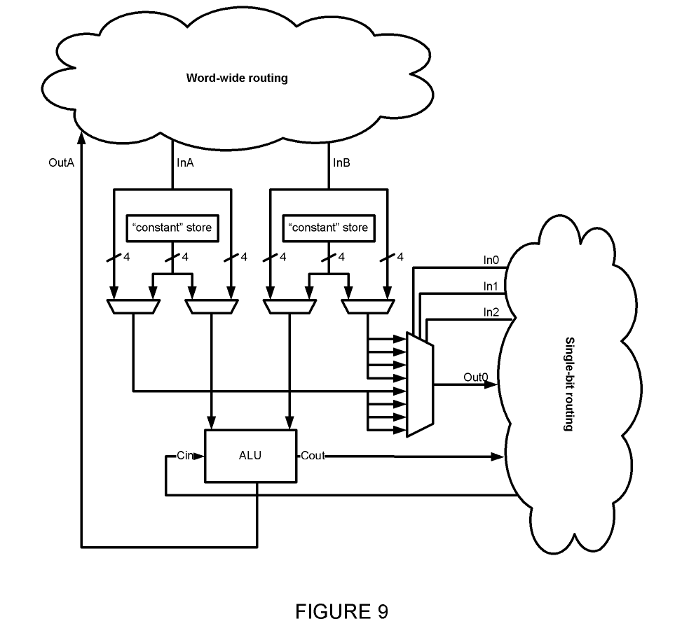

FIG. 9 is a functional diagram of a circuit in accordance with yet another embodiment of the present invention;

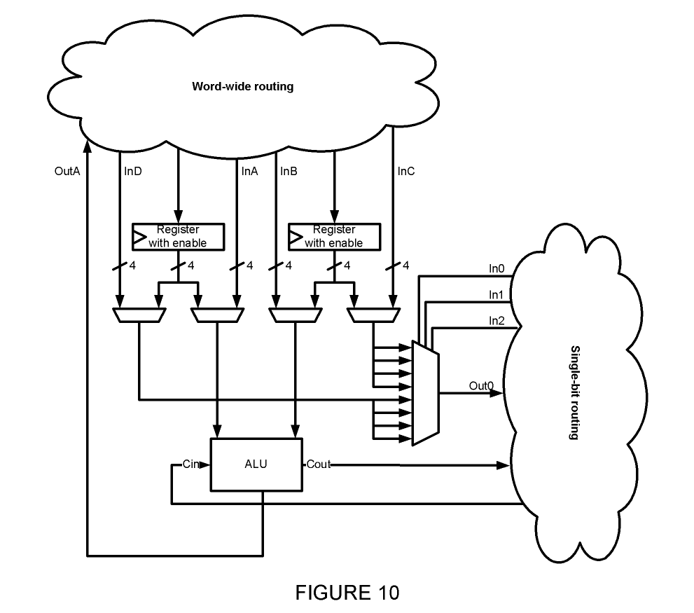

FIG. 10 is a functional diagram of a circuit in accordance with a further embodiment of the present invention;

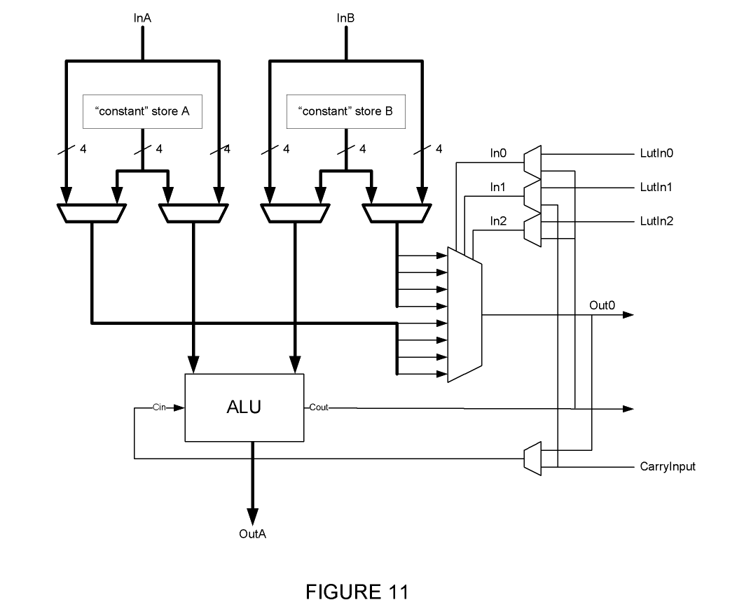

FIG. 11 is a functional diagram of a circuit in accordance with another embodiment of the present invention; and

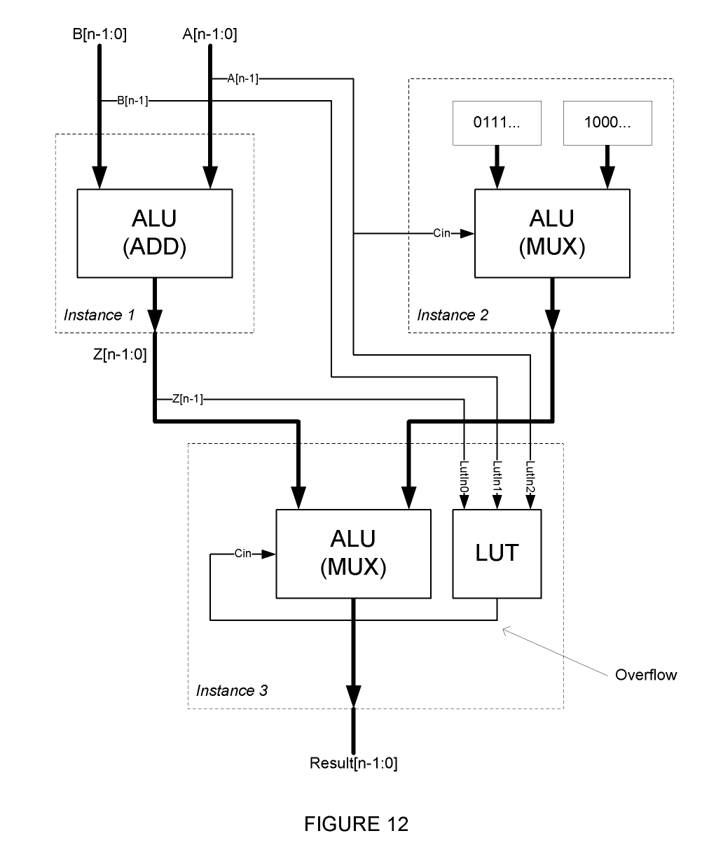

FIG. 12 is a functional diagram of a circuit for performing saturated arithmetic in accordance with an embodiment of the present invention.

FIG. 1 is a functional diagram of a Look-up-Table (LUT) 10 in accordance with one example of the prior art. A LUT 10 is basically a small memory M₀-M₇ that stores the truth table for a particular Boolean function. Because of their small size however, LUTs 10 are not normally implemented in the same way as larger memories. As can be seen from FIG. 1, LUT 10 comprises a number of memory elements M₀ to M₇ that connect to a tree of multiplexers 1. The control inputs to the multiplexers In0, In1, In2 enable the selection of one of the memory elements to connect to the output out0. As can be deduced from FIG. 1, to build an N-input LUT requires 2N memory elements, and (2N−1)/(M−1) M-input multiplexers.

Because the LUT 10 stores a truth table directly, it can implement any Boolean function of its inputs. This makes LUT-based architectures particularly advantageous when implementing applications that can be decomposed into a number of complex functions of a small number of inputs. A small state machine with a complex set of transitions between the states is an example of such an application.

LUT-based architectures are however not particularly efficient at implementing functions with considerably more inputs than a basic LUT provides. For example, the output of the most-significant bit of a 32-bit adder depends on all bits of both 32-bit inputs (64 bits in total). LUT-based architectures therefore often contain extra logic to try to improve carry propagation for arithmetic functions.

Dissimilarly, ALUs are circuits specifically designed for processing word-based data. A typical ALU has two word-wide inputs, and one word-wide output. It may also have a small number of single bit inputs, and a similar number of single-bit outputs. These single bit inputs and outputs are used to pass control signals between ALUs. For example, one ALU may perform a comparison function, and the result is used to control another ALU that is acting as a multiplexer. The functions that an ALU can perform are described in terms of the way that they transform the input words, rather than their effect on the individual bits. For example, the functional of an ALU can be described as “add”, “subtract” or “test for equality”.

An ALU may however only provide a small number of functions, such as those listed in the table of FIG. 2. Whilst when compared to the 2¹⁶ possible functions that a 4-input LUT can provide, this number may appear quite small, it is chosen to provide the common functions that are applied to word-wide data in typical applications.

What the applicant has realised is that when comparing ALUs and LUTs in greater detail, it is possible to find certain complimentary properties. For example, LUTs efficiently implement arbitrary functions of a small number of unstructured input bits, but are significantly less efficient when dealing with functions with a large number of inputs. Conversely, ALUs efficiently implement a small number of functions of word-wide data. In essence, they exploit knowledge of the structure of the input data (i.e. its organisation as words) to provide a compact implementation of an important subset of the complete list of possible functions. ALUs are less efficient when the data lacks this kind of structure, or uses functions outside the chosen subset.

One further difference between LUTs and ALUs relates to the way that they use constants in a circuit design. In a LUT-based architecture, constants can always be optimised away. For instance a comparison to a constant:

A=B[3:0]==4'b1101;

A=(B[3]==1)&(B[2]==1)& (B[1]==0)&(B[0]==1);

A=!(B[3]̂1)&!(B[2]̂1)& !(B[1]̂0)&!(B[0]̂1);

A=B[3]&B[2]&!B[1]&B[0];

The result of this is an arbitrary function of a group of input bits, which function is the type which can easily then be mapped into one or more LUTs.

In an ALU-based architecture, the implementation of the above example is different. For an ALU-based circuit, the equality test would be mapped onto an ALU implementing an EQUALS operation and, separately, a constant would be created and stored in a register in the array. The circuit would then compare a word-wide first input of the ALU with the input which is connected to the register. Accordingly, an ALU-based architecture has a greater need for registers to store these constants, than does a LUT-based architecture.

As mentioned above, ALU-based architectures process words rather than individual bits. It is however sometimes necessary to access individual bits within a word. Therefore, an ALU-based architecture needs some way to test and/or set individual bits within a word. This can be done either by extending (i.e. adding additional instructions) the ALU to include such test and set operations, or by including separate logic for such purposes.

In order to create a hybrid architecture of ALUs (for processing word-based data) and LUTs (for processing unstructured data), the prior art teaches towards having a group of ALUs and a separate group of LUTs having control signals passing back and forth between the separate groups. Contrary to this approach, the present invention integrates a LUTs and ALUs into a single integrated unit, which does not require external routing in order to operate.

FIG. 3 is a functional diagram of a circuit in accordance with a first embodiment of the present invention. As can be seen, the LUT separated into memory and multiplexer sections. The first four bits of the LUT are connected to the output of multiplexer 3, which has InC and constant store M₀ to M₃ as inputs. The last four bits of the multiplexer tree are connected to constant store M₄ to M₇. Accordingly, the memory is grouped into units that contain the same number of bits as an input word to the ALU. Multiplexers 2 and 3 are provided so that ALU inputs can be connected to either an external input InB, or to constant store M₀ to M₃. Similarly, multiplexer 3 allows the multiplexer tree of the LUT to have its inputs connected to either the memory units or to external input InC.

The constant memory is therefore usable as either a constant input to the ALU, or as the Boolean function store for the LUT.

As will be appreciated by the skilled reader, the above described circuit can operate in several different ways. For example, the circuit can operate as an ALU with externally supplied inputs InA and InB, and a LUT with locally stored data. Furthermore, the circuit can operate as an ALU with a constant input and externally supplied input InA, and a multiplexer tree that can select a bit from word-wide input InC. Moreover, the circuit can also operate as an ALU with externally supplied inputs InA and InC, and a multiplexer tree that can select a bit from a word-wide input. There may also be circumstances where the same constant value is needed by both the ALU and the LUT, so that it is possible to combine an ALU (with a constant input) and a LUT together. Providing this flexibility in a local area is a major advantage of the invention.

As will now be described, the present invention can take one of three basic forms, depending on the relative widths of the LUT constant store, and the ALU wordlength.

The form is where the ALU wordlength is less than the LUT memory size. This situation is shown in FIG. 3. The LUT requires more memory bits than are present in an ALU word. Given that the number of LUT memory bits must be a power of two, and that the ALU wordlength is commonly also to the power of two, this implies that the memory bits can be evenly divided into an integer number of ALU wordlength sized groups. FIG. 3 shows the case of a 3-input LUT with a group of eight memory bits, which group is divided into two 4-bit words.

In a situation where more than one wordlength-sized group is present, it is possible to add optional constants to more than one ALU input in the manner shown in FIG. 3. There are two basic options to do this. The first option sees the addition of constants to more than one input of the same ALU, for instance as shown in FIG. 4.

The second option sees the addition of constants to inputs of more than one ALU, as shown in FIG. 5. As will be appreciated, in the embodiment of FIG. 5, it is possible for the ALUs to be independent with respect to their inputs, or arranged in series. It is also possible for the two ALUs to have the same set of basic operations, or for them to be different, in particular one could be significantly simper than the other, for example, in the case where one of the ALUs is simply a multiplexer.

As will also be appreciated by the skilled reader, it is possible to combine these options, and have multiple constants connecting to each of multiple ALUs. It is also possible for a single constant connect to multiple ALUs.

The second basic form of the present invention is where the ALU wordlength is equal to the LUT memory size. This situation is shown in FIG. 8, and is effectively a simplification of FIG. 3. This embodiment of the present invention comprises a single constant, and there is therefore no need to consider how to connect multiple constants. This simplification however comes at the cost of losing the ability to directly evaluate simple functions of a bit from the word-wide inputs and one of the single-bit inputs.

Finally, the third basic form of the present invention is when the ALU wordlength is greater than the LUT memory size. This situation is shown in FIG. 6. Here the mux tree is still able to operate as a LUT, but has lost the ability to access an arbitrary bit from an ALU word. This ability could be restored by adding extra multiplexer trees connected to other parts of the input word, thought this solution is essentially equivalent to creating a single larger multiplexer tree, and returning to the structure where the ALU wordlength is equal to the LUT memory size. The embodiment of FIG. 6 shows 8-bit wordlength. As will be appreciated by the skilled reader, all of the embodiments of the present invention will work with any wordlength.

As will be appreciated from the above description, the most flexible structure is the first, where the LUT memory size is greater than the ALU wordlength, and the wordlength is a factor of the memory size. The applicant has realised that the preferred size of LUT is one with between 3 and 6 inputs, i.e. needing between 8 and 64 memory bits. In turn, this implies that the invention is best used with ALUs with sizes that are smaller than this.

The present invention can be used advantageously in a great many situations, one of which is shown in FIG. 8, which is a variant of FIG. 4. FIG. 8 shows possible connections between the terminals of the ALU and multiplexer tree, and the routing networks(s) of the reconfigurable array.

Arrays with separate word-wide and single-bit routing networks are known from the prior art. In such an array, the circuit of the present invention is sufficient to provide gateways from single-bit to multi-bit routing, and from multi-bit to single-bit routing. As can be seen from FIG. 8, with appropriate constants on In0, In1, In2 it is possible to select a bit from the multi-bit InC input to connect to the single-bit Out0 output. Moreover, by using the ALU as a multiplexer, it is possible to use a 1-bit signal (on Cin) to select between the two word-wide constants. If these are set to, for example, 0001 and 0000, it is possible to send a word-wide version of a single-bit value into the word-wide routing network. As will be appreciated, it is of course also possible to construct dedicated gateways between the two networks to supplement the use of the present invention.

Alternative embodiments of the present invention will now be described with reference to FIGS. 9 and 10. The embodiments may be used separately, or may be combined together. The first of these alternative embodiments will now be described with reference to FIG. 9, which shows the use of registers as memory elements. In this embodiment, instead of dedicated storage for the constant memory, this circuit uses registers with an enable signal. The structure advantages of this embodiment are twofold. Firstly, this modification allows a register to be added to the input to either the ALU or the multiplexer tree and, secondly, this modification allows a constant to be placed at the input to the ALU or the multiplexer tree, if the register is permanently disabled.

The functional advantage of this embodiment is the increased design flexibility it provides. The disadvantage however is that the register cell is larger than a constant cell. Therefore, this extension is typically only advantageously used in designs that require large numbers of registers, for instance for a high-speed design that requires a large number of registers to “pipeline” it. As will be appreciated by the skilled reader, “pipelining” is a method used to increase the operating frequency of an application by inserting added registers into the application in such a way that the length (delay) of the longest combinatorial path is reduced. Although the resulting circuit has a higher operating frequency, it also has a longer delay (in terms of clock cycles) and requires the use of extra registers.

Another alternate embodiment of the present invention is shown in FIG. 10, which represents a circuit having shared connections to the routing network of the programmable logic device. Here, the number of inputs to the circuit is reduced by pairing up ALU inputs and multiplexer tree inputs. The result is that each pair of ALU/multiplexer tree inputs shares one constant source and one external input.

Whilst this embodiment constrains the use of the ALU and multiplexer tree, since they cannot use independent external inputs, it also reduces the size of the routing network since it no longer needs to support independent connections to both ALU and multiplexer tree. This modification results in an area saving for designs that use a large number of constants, either for the ALUs, or because they contain many LUTs.

The present invention can be used in a wide variety of circuits. For example, FIG. 11 shows an option for part of the single-bit routing circuit of FIG. 10. This provides for several connection options between the ALU and the LUT. For example, LUT input In0 can connect to either ALU Cout, or an external signal (LutIn0), LUT input In1 can connect to either CarryInput (the external ALU Cin source), or another external signal (LutIn1) and LUT input In2 can connect to either ALU Cout, or an external signal (LutIn2) (i.e. a similar connection to that for In0). Also, ALU Cin can connect to either the LUT output, or to an external signal (CarryInput).

A particular advantage of this circuit is that it can be used to implement functions that combine the operation of ALU and LUT, as described in the following examples.

The first example is where the LUT output connects to ALU Cin, and ALU implements a multiplexer function. With InA/B connected to the ALU, and the constants connected to the LUT, the ALU-based multiplexer can be controlled by an arbitrary function of the LUT inputs In0, In1, In2. i.e.:

OutA=F(In0,In1,In2)?InA:InB.

The above-described first example can be advantageously used in a circuit arranged to perform saturated arithmetic, as will now be described with reference to FIG. 12. In saturated arithmetic, if the result of a calculation overflows (i.e. it requires more bits to store the correct answer than are available), then the result is replaced with the nearest possible number that can be represented.

In the case of the addition of two signed numbers, there are two possible overflow conditions. The first overflow condition is when two positive n-bit numbers add to give a result that is larger than the most positive number that can be represented in n bits. In this case, the calculated result is replaced with the most-positive n-bit signed integer—a leading 0 followed by (n−1) 1s.

The second overflow condition is when two negative n-bit numbers add to give a result that is smaller (more negative) than the most negative number that can be represented in n bits. In this case, the calculated result is replaced with the most-negative n-bit signed integer—a leading 1 followed by (n−1) 0s.

If a positive and a negative number are summed, the result cannot overflow—it must lie in the legal range.

FIG. 12 shows a circuit to implement a saturated add, using three copies of a circuit in accordance with the present invention:

Instance1 of the circuit uses the ALU in order to compute the sum of A and B:

Z[n−1:0]=A[n−1:0]+B[n−1:0]

Instance2 of the circuit uses the ALU and the input constants to generate the possible saturation value. Here, the ALU is used as a multiplexer to choose between the two possible constant values, and is controlled by the sign bit (the most significant bit) of A.

Overflow_val[n−1:0]=A[n−1]?1000 . . . : 0111 . . . ;

Instance 3 of the circuit uses the LUT to determine whether an overflow has occurred, and then uses the ALU as a multiplexer to choose between the result of the initial addition and the saturation value:

Overflow=(A[n−1]==B[n−1]&(A[n−1]!=Z[n−1];

i.e. the inputs have same sign but the output does not have the same sign.

Result=overflow?overflow_val:Z;

A second example of an advantageous circuit implemented using the present invention is where the ALU Cout connects to LUT In0, and the ALU implements an EQUALS function. With InA/B connected to the ALU, and the constants connected to the LUT, the LUT can generate an arbitrary function of the ALU Cout, and the LUT inputs In1, In2. i.e.:

$$\begin{matrix}Out 0 = F ( Cout , In 1 , In 2 ) ; \\ = F ( InA == InB , In 1 , In 2 ) ;\end{matrix}$$

This type of function is a useful building block when constructing state machines, where the next state may depend on both the current state, and the values of one or more inputs. For instance, the ALU may test the inputs, while In1 and In2 are derived from the current state of the state machine.

Also, this type of connection can be used to combine multiple tests into a single result. For example, if In1 is connected (via LutIn1) to the carry output of another ALU elsewhere in the array, it becomes possible to construct more complex tests, such as:

Out0=F(InA==InB, InC<InD,In2);

where InC and InD are the inputs to the second ALU. For instance, F may be an OR of its various inputs, which allows for the construction of more complex state machines, with more complex transition conditions.

A third example of is where a combination of multiple comparisons occurs when performing an equality test function for words that are wider than the native wordlength of the ALU. Ordinarily, this would use multiple ALUs in series, linked together by connecting the Cout of one ALU to the Cin of another. However, such a comparison will fail if the partial match in any individual ALU fails. Using the connection from Cin to the LUT In1 input increases the speed of this kind of function. If Cin indicates a failure of the comparison in an earlier part of the word, this can propagate directly to the LUT output, rather than going via the ALU Cin-to-Cout circuit.

The preceding examples connect the constants to the LUT. However, it is also possible to connect one of the stored constants to the ALU. For example, by connecting the constant store B to the ALU. Then the ALU can compare to a constant:

Cout=InA==ConstB

The LUT can then be connected to InB and constant store A. if the LUT inputs In0 and In1 are both set to constant 0, and In2 is connected to ALU Cout, then:

Out0=In22?ConstantA[0]:InB[0],

and in the case where ConstantA[0] is 1, this becomes:

$$\begin{matrix}Out 0 = In 2 ? 1 : InB [ 0 ] \\ = In 2 \vert InB [ 0 ] \\ = ( InA == ConstB ) \vert InB [ 0 ] ,\end{matrix}$$

which is equivalent to an OR of the result of the comparison, and an external input bit. Changing the values of the constants on In0 and In1 will change the bit of InB that is used in this function.

Similarly, connecting the constant store A to the ALU, and constant store B to the LUT results in a function of the form:

Out0=In2?InA[i]:ConstB[i],

with ConstB equal to 0, it can be seen that:

$$\begin{matrix}Out 0 = In 2 ? InA [ i ] : 0 \\ = In 2 \& InA [ i ] \\ = ( InB == ConstA ) \& InA [ i ] ,\end{matrix}$$

which is equivalent to an AND of the result of the comparison, and an external input bit. As will be appreciated, all of the above circuits can be implemented using the basic circuit of the present invention.

1. A combinatorial processing element used in a reconfigurable logic device having a plurality of processing elements interconnected by way of a routing network, the combinatorial processing element including:
an arithmetic logic unit, having at least one input;
a multiplexer tree, having a data input; and
a memory device,
wherein the processing element is arranged such that the memory can be connected to the data input of the multiplexer tree and/or the at least one input of the arithmetic logic unit.

2. The combinatorial processing element of claim 1, further comprises:
an input arranged to be connected to the routing network of the reconfigurable device.

3. The combinatorial processing element of claim 1, wherein:
the at least one input of the arithmetic logic unit is an N-bit input;
the multiplexer tree further comprises M select inputs and 2^{M} data inputs, the multiplexer tree being arranged to select any of the 2^{M} data inputs; and
the memory device is an N-bit memory device arranged to be connected to the N-bit input of the ALU and/or to N of the 2^{M} data inputs of the multiplexer tree.

4. The combinatorial processing element of claim 3, wherein N is smaller or equal to one half of 2^{M} and the combinatorial processing element further comprises:
a plurality of memory devices, wherein each of the plurality of memory devices is arranged to be connected to a separate input of the arithmetic logic unit and/or separate data inputs of the multiplexer tree.

5. The combinatorial processing element of claim 1, wherein: the at least one input of the arithmetic logic unit is an N-bit input;
the multiplexer tree comprises M select inputs and an N-bit data input, the multiplexer tree being arranged to select one bit of the N-bit data input; and
the memory device is an N-bit memory device arranged to be connected to the N-bit input of the ALU and/or to N of the 2^{M} data inputs of the multiplexer tree.

6. The combinatorial processing element of claim 5, further comprising:
at least one N-bit input connected to the routing network of the reconfigurable logic device.

7. The combinatorial processing element of claim 6, wherein:
the sum of N-bit inputs of the ALU and N-bit inputs of the multiplexer tree is more than the number of N-bit inputs connected to the routing network of the reconfigurable logic device.

8. The combinatorial processing element of claim 1, wherein the memory devices are registers which are connected to the routing network of the reconfigurable logic device.

9. A reconfigurable logic device comprising:
a combinatorial processing element of claim 1.

10. The reconfigurable logic device of claim 9, wherein at least one combinatorial processing element is arranged to provide a gateway between a single-bit routing network and a multi-bit routing network in the reconfigurable logic device.
